(19) United States
(12) Patent Application Publication
(10) Pub. No.: US 2026/0052816 A1
(43) Pub. Date: Feb. 19, 2026

(54) DISPLAY PANEL AND MANUFACTURING METHOD THEREOF

(71) Applicant: TCL CHINA STAR OPTOELECTRONICS TECHNOLOGY CO., LTD., Shenzhen (CN)

(72) Inventors: Haofeng ZHANG, Shenzhen (CN); Weijing ZENG, Shenzhen (CN); Jiangbo YAO, Shenzhen (CN); Zhifu LI, Shenzhen (CN)

(73) Assignee: TCL CHINA STAR OPTOELECTRONICS TECHNOLOGY CO., LTD., Shenzhen (CN)

(21) Appl. No.: 19/004,390

(22) Filed: Dec. 29, 2024

(30) Foreign Application Priority Data
Aug. 16, 2024 (CN) 202411132911.X

(51) Int. Cl. H10H 29/01; H10H 29/34; H10H 29/80; H10K 59/12; H10K 59/35; H10K 59/80; H10K 71/60; H10K 102/00

(52) U.S. Cl. CPC H10H 29/032; H10H 29/012; H10H 29/34; H10H 29/8321; H10K 59/1201; H10K 59/353; H10K 59/80515; H10K 59/80517; H10K 71/60; H10K 2102/351

(57) ABSTRACT

The present disclosure provides a display panel. The display panel includes: a substrate, a driving circuit layer, and a light-emitting device layer. The light-emitting device layer includes a plurality of light-emitting devices. Each light-emitting device includes an anode, a light-emitting layer, and a cathode. The anode includes a first transparent electrode, a first metal electrode, and a second transparent electrode, where the first metal electrode is disposed on one side of the first transparent electrode away from the driving circuit layer, the second transparent electrode is disposed on one side of the first metal electrode away from the first transparent electrode, and the first metal electrode is wrapped between the first transparent electrode and the second transparent electrode.

### CROSS-REFERENCE TO RELATED APPLICATION

This application claims priority to and the benefit of Chinese Patent Application No. 202411132911.X, filed on Aug. 16, 2024, the disclosure of which is incorporated herein by reference in its entirety.

### TECHNICAL FIELD

The present disclosure relates to the field of display technology, and in particular to a display panel and a manufacturing method thereof.

### BACKGROUND

Quantum dots are nanocrystalline particles with a radius smaller than or close to the Bohr exciton radius, typically ranging from 1 nanometer to 20 nanometers. Quantum dots exhibit a quantum confinement effect and can emit fluorescence when excited. Quantum dots possess unique luminescent properties, such as a wide excitation peak, a narrow emission peak, and an adjustable luminescence spectrum, making them highly promising in the field of photoelectric luminescence. Quantum dot light-emitting diodes (QD-LEDs) are electroluminescent devices utilizing quantum dots as the light-emitting layer, introducing the quantum dots light-emitting layer between different conductive materials to achieve a desired wavelength of light. Over the past two decades, QD-LED display technology has emerged as a highly competitive contender for the next generation of displays due to its advantages, including tunable size and wavelength, extremely narrow emission peak width, wide color gamut, high electroluminescence efficiency, and reduced losses through solution-based processes.

In a manufacturing process of the QD-LED devices, a stacked structure consisting of a transparent metal oxide layer/metal layer/transparent metal oxide layer is commonly used as an anode of the devices. However, during the manufacturing process, there may be sharp protrusions formed on an edge of the metal layer in the anode, which cannot be effectively covered by the light-emitting layer. Consequently, when a cathode is subsequently formed, the cathode comes into contact with the protrusions on the edge of the metal layer, resulting in a direct connection between the cathode and the anode, causing a short circuit. As a result, the quantum dot light-emitting diode fails to emit light, leading to the appearance of a dark dot on a display screen.

Therefore, it is necessary to provide a display panel a manufacturing method thereof to mitigate this defect.

### SUMMARY

In an aspect, some embodiments of the present disclosure provide a display panel, including:
a substrate;
a driving circuit layer disposed on one side of the substrate;
a light-emitting device layer disposed on one side of the driving circuit layer away from the substrate, wherein the light-emitting device layer includes a plurality of light-emitting devices, each light-emitting device comprises an anode, a light-emitting layer, and a cathode, wherein the light-emitting layer is disposed on one side of the anode away from the driving circuit layer, and the cathode is disposed on one side of the light-emitting layer away from the anode.

The anode includes a first transparent electrode, a first metal electrode, and a second transparent electrode, the first metal electrode is disposed on one side of the first transparent electrode away from the driving circuit layer, the second transparent electrode is disposed on one side of the first metal electrode away from the first transparent electrode, and the first metal electrode is wrapped between the first transparent electrode and the second transparent electrode.

In some embodiments, the second transparent electrode is continuously disposed on a surface of the first metal electrode away from the first transparent electrode and on a side surface of the first metal electrode.

In some embodiments, an orthographic projection of the first metal electrode on the substrate is located within an orthographic projection of the second transparent electrode on the substrate.

In some embodiments, an orthographic projection of the first metal electrode on the first transparent electrode is located within the first transparent electrode.

In some embodiments, the second transparent electrode is continuously disposed on the side surface of the first metal electrode and on a side surface of the first transparent electrode.

In some embodiments, the plurality of light-emitting devices include a red light-emitting device, a green light-emitting device, and a blue light-emitting device. A surface of the anode of the red light-emitting device away from the substrate is lower than a surface of the anode of the green light-emitting device away from the substrate, and the surface of the anode of the green light-emitting device away from the substrate is lower than a surface of the anode of the blue light-emitting device away from the substrate

In some embodiments, the plurality of light-emitting devices include a red light-emitting device, a green light-emitting device, and a blue light-emitting device. A surface of the anode of the red light-emitting device away from the substrate is flush with a surface of the anode of the green light-emitting device away from the substrate and a surface of the anode of the blue light-emitting device away from the substrate.

In some embodiments, the plurality of light-emitting devices include a red light-emitting device, a green light-emitting device, and a blue light-emitting device. A thickness of the second transparent electrode of the red light-emitting device is smaller than a thickness of the second transparent electrode of the green light-emitting device, and the thickness of the second transparent electrode of the green light-emitting device is smaller than a thickness of the second transparent electrode of the blue light-emitting device.

In some embodiments, a thickness of the first metal electrode of the red light-emitting device is greater than or equal to a thickness of the first metal electrode of the green light-emitting device, and the thickness of the first metal electrode of the green light-emitting device is greater than or equal to a thickness of the first metal electrode of the blue light-emitting device.

In some embodiments, each second transparent electrode includes a first transparent sub-electrode and a second transparent sub-electrode, the second transparent sub-electrode is disposed on one side of the first transparent sub-electrode away from the first metal electrode adjacent to the second transparent electrode, and surface roughness of the first transparent sub-electrode is greater than surface roughness of the second transparent sub-electrode.

In another aspect, some embodiments of the present disclosure further provide a method for manufacturing a display panel including at least a red light-emitting device, a green light-emitting device, and a blue light-emitting device, including:
forming a substrate;
forming a driving circuit layer on the substrate;
forming a first transparent electrode material layer and a first metal electrode material layer on the driving circuit layer in sequence;
etching the first transparent electrode material layer and the first metal electrode material layer to form a first transparent electrode and a first metal electrode of each of the red light-emitting device, the green light-emitting device, and the blue light-emitting device;
forming a second transparent electrode material layer on each first transparent electrode, each first metal electrode, and the driving circuit layer, and etching the second transparent electrode material layer to form a second transparent electrode of the red light-emitting device and expose the first metal electrode of the green light-emitting device and the first metal electrode of the blue light-emitting device;
forming a third transparent electrode material layer on each first transparent electrode, each first metal electrode, each second transparent electrode, and the driving circuit layer, and etching the third transparent electrode material layer to form a second transparent electrode of the green light-emitting device and expose the second transparent electrode of the red light-emitting device and the first metal electrode of the blue light-emitting device; and
forming a fourth transparent electrode material layer on each first transparent electrode, each first metal electrode, each second transparent electrode, and the driving circuit layer, and etching the fourth transparent electrode material layer to form a second transparent electrode of the blue light-emitting device and expose the second transparent electrode of the red light-emitting device and the second transparent electrode of the green light-emitting device.

In still another aspect, some embodiments of the present disclosure further provide another method for manufacturing a display panel including at least a red light-emitting device, a green light-emitting device, and a blue light-emitting device, including:
forming a substrate;
forming a driving circuit layer on the substrate;
forming a first transparent electrode material layer and a first metal electrode material layer on the driving circuit layer in sequence;
etching the first transparent electrode material layer and the first metal electrode material layer to form a first transparent electrode of each of the red light-emitting device, the green light-emitting device, and the blue light-emitting device, and expose the first transparent electrode of each of the green light-emitting device and the blue light-emitting device while leave a top surface of the first transparent electrode of the red light-emitting device being covered by a remaining part of the first metal electrode material;
forming a second metal electrode material layer on the remaining part of first metal electrode material layer, and each first transparent electrode, and etching the second metal electrode material layer to expose the first transparent electrode of the blue light-emitting device while leave a top surface of the remaining part of first metal electrode material layer of the red light-emitting device and a top surface of the first transparent electrode of the green light-emitting device being covered by a remaining part of the second metal electrode material;
forming a third metal electrode material layer on the second metal electrode material layer and the first transparent electrode, and etching the third metal electrode material layer to form a first metal electrode of each of the red light-emitting device, the green light-emitting device, and the blue light-emitting device;
forming a first transparent sub-electrode material layer on the driving circuit layer and each first metal electrode;
forming a second transparent sub-electrode material layer on the first transparent sub-electrode material layer;
etching the first transparent sub-electrode material layer and the second transparent sub-electrode material layer to form a first transparent sub-electrode and a second transparent sub-electrode of each light-emitting device; and
forming a pixel definition layer on each second transparent sub-electrode and the driving circuit layer, and etching the pixel definition layer to form at least three pixel openings respectively corresponding to the red light-emitting device, the green light-emitting device, and the blue light-emitting device.

### BRIEF DESCRIPTION OF THE DRAWINGS

FIG. 1 is a schematic structural diagram of a first display panel according to some embodiments of the present disclosure.

FIG. 2 is a schematic structural diagram of an anode of the first display panel according to some embodiments of the present disclosure.

FIGS. 3a to 3e are schematic diagrams showing a manufacturing process of the first display panel according to some embodiments of the present disclosure.

FIG. 4 is a schematic structural diagram of a second display panel according to some embodiments of the present disclosure.

FIGS. 5a to 5i are schematic diagrams showing a manufacturing process of the second display panel according to some embodiments of the present disclosure.

FIG. 6 is a schematic structural diagram of a display device according to some embodiments of the present disclosure.

### DETAILED DESCRIPTION

The following description of embodiments refers to the accompanying drawings to illustrate specific embodiments in which the present disclosure may be implemented. The directional terms mentioned in the present disclosure, such as “upper”, “lower”, “front”, “back”, “left”, “right”, “inner”, “outer”, “side”, etc., are merely directions with reference to the accompany drawings. Therefore, the directional terms used are used to explain and understand the present disclosure, but not to limit the present disclosure. In the figures, units with similar structures are represented by the same number.

The present disclosure will be further described below in conjunction with the accompanying drawings and specific embodiments.

Some embodiments of the present disclosure provide a display panel that can mitigate dark spots appearing on the display panel.

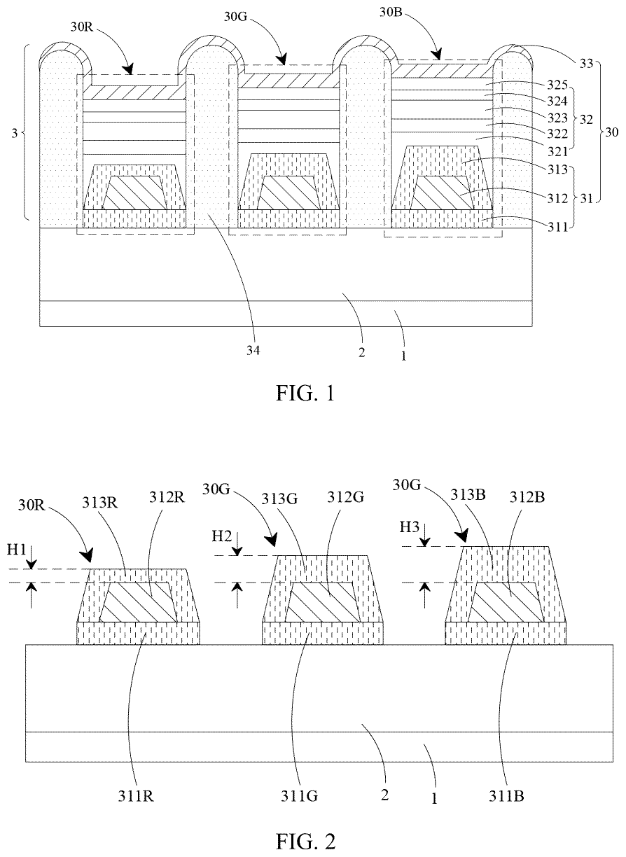

FIG. 1 is a schematic structural diagram of a first display panel according to some embodiments of the present disclosure. The display panel includes a substrate 1, a driving circuit layer 2, and a light emitting device layer 3, as described in conjunction with FIG. 1. The driving circuit layer 2 is disposed on the substrate 1. The light emitting device layer 3 is disposed on a side of the driving circuit layer 2 away from the substrate 1. The light-emitting device layer 3 includes a plurality of light-emitting devices 30. Each light-emitting device 30 includes an anode 31, a light-emitting layer 32, and a cathode 33. The light-emitting layer 32 is disposed on a side of the anode 31 away from the driving circuit layer 2, and the cathode 33 is disposed on a side of the light-emitting layer 32 away from the anode 31.

In some embodiments, the anode 31 includes a first transparent electrode 311, a first metal electrode 312, and a second transparent electrode 313. The first metal electrode 312 is disposed on a side of the first transparent electrode 311 away from the driving circuit layer 2, the second transparent electrode 313 is disposed on a side of the first metal electrode 312 away from the first transparent electrode 311, and the first metal electrode 312 is wrapped between the first transparent electrode 311 and the second transparent electrode 313.

In the embodiments, by wrapping the first metal electrode 312 between the first transparent electrode 311 and the second transparent electrode 313, the cathode 33 may be prevented from contacting any sharp protrusion formed on an edge of the first metal electrode 312, which avoids the cathode 33 from direct contact with the anode 31. By avoiding the direct contact between the cathode 33 and the anode 31, a risk of a short circuit is effectively minimized. This crucially prevents the light-emitting device 30 from failing to emit light, thereby mitigating the occurrence of the dark spots on the display panel.

In some embodiments, the second transparent electrode 313 is continuously disposed on a surface (i.e. the top surface as shown in the figures) of the first metal electrode 312 away from the first transparent electrode 311 and on a side surface of the first metal electrode 312.

As shown in FIG. 1, the top surface of the first metal electrode 312 away from the first transparent electrode 311 is a flat surface. A side surface of the first metal electrode 312 refers to an inclined surface connecting the top surface of the first metal electrode 312 away from the first transparent electrode 311 and a surface (i.e. the bottom surface as shown in the figures) of the first metal electrode 312 close to the first transparent electrode 311. As used herein, the side surface of the second metal electrode 312 refers to its entire side surface, which may by a cylindrical surface of a cylindrical second metal electrode 312, or four side surfaces of a square second metal electrode 312, or the like. The side surface of the first metal electrode 312 and the bottom surface of the first metal electrode 312 close to the first transparent electrode form an acute angle, which facilitates depositing and forming the second transparent electrode 313 on the side surface of the second metal electrode 312.

As shown in FIG. 1, the second transparent electrode 313 is continuously disposed on the top surface of the first metal electrode 312 away from the first transparent electrode 311 and on the side surface of the first metal electrode 312. That is, the second transparent electrode 313 continuously covers the top surface of the first metal electrode 312 away from the first transparent electrode 312 and the side surface of the first metal electrode 312. By covering the top surface and side surface of the first metal electrode 312 with the second transparent electrode 313, the cathode 33 may be prevented from contacting any sharp protrusion formed on the edge of the first metal electrode 312, thereby preventing the cathode 33 from contacting the anode 31. Such isolation between the cathode 33 and the anode 31 avoids a short circuit from occurring in the light-emitting device 30.

In some embodiments, an orthographic projection of the first metal electrode 312 on the substrate 1 is located within an orthographic projection of the second transparent electrode 313 on the substrate 1.

As shown in FIG. 1, a peripheral edge of (the orthographic projection of) the second transparent electrode 313 exceed a peripheral edge of (the orthographic projection of) the first metal electrode 312, and an area of the orthographic projection of the first metal electrode 312 on the substrate 1 is smaller than an area of the orthographic projection of the second transparent electrode 313 on the substrate 1. In this way, the orthographic projection of the first metal electrode 312 on the substrate 1 is entirely within the orthographic projection of the second transparent electrode 313 on the substrate 1, thereby ensuring that the second transparent electrode 313 may completely cover the first metal electrode 312 and completely isolate the first metal electrode 312 from the light-emitting layer 32 and the cathode 33, thereby preventing the cathode 33 from contacting any sharp protrusion formed on the edge of the first metal electrode 312.

In some embodiments, an orthographic projection of the first metal electrode 312 on the first transparent electrode 311 is located within the first transparent electrode 311.

As shown in FIG. 1, a peripheral edge of (the orthographic projection of) the first transparent electrode 311 exceeds the peripheral edge of the first metal electrode 312, and the second transparent electrode 313 is not only disposed on the top surface of the first metal electrode 312 away from the first transparent electrode 311 and the side surface of the first metal electrode 312, but also disposed on the surface part of the first transparent electrode 311 not covered by the first metal electrode 312. In this way, the first transparent electrode 311 and the second transparent electrode 313 can form an enveloping structure for the first metal electrode 312, completely covering or enveloping the top surface, bottom surface, and side surface of the first metal electrode 312, thereby avoiding the contact between the cathode 33 and any sharp protrusion formed on the edge of the first metal electrode 312, further reducing the risk of dark spots on the display panel due to a short circuit between the anode 31 and the cathode 33.

Some embodiments are as shown in FIG. 1 and FIG. 2, where FIG. 2 is a schematic structural diagram of an anode of the first display panel according to some embodiments of the present disclosure. In these embodiments, the light-emitting device 30 includes a red light-emitting device 30R, a green light-emitting device 30G, and a blue light-emitting device 30B. The red light-emitting device 30R is used to emit red light, the green light-emitting device 30G is used to emit green light, and the blue light-emitting device 30B is used to emit blue light. A surface of the anode of the red light-emitting device 30R away from the substrate 1 is lower than a surface of the anode of the green light-emitting device 30G away from the substrate 1, and the surface of the anode of the green light-emitting device 30G away from the substrate 1 is lower than a surface of the anode of the blue light-emitting device 30B away from the substrate 1.

In some embodiments, a thickness H1 of a second transparent electrode 313R of the red light-emitting device 30R is smaller than a thickness H2 of a second transparent electrode 313G of the green light-emitting device 30G, and the thickness H2 of the second transparent electrode 313G of the green light-emitting device 30G is smaller than a thickness H3 of a second transparent electrode 313B of the blue light-emitting device 30B. In this way, different light-emitting devices may have different microcavity lengths to improve a light coupling efficiency of each light-emitting device, thereby improving a luminous efficiency of each light-emitting device.

It should be noted that the thickness H1 of the second transparent electrode 313R of the red light-emitting device 30R refers to a thickness of a part of the second transparent electrode 313R on the top surface of the first metal electrode 312R of the red light-emitting device 30R away from the first transparent electrode 311R. The same is true for the thickness of the second transparent electrode of the other light-emitting devices, which will not be described again here.

In some embodiments, as shown in FIG. 1, a thickness of the anode of the red light-emitting device 30R is less than a thickness of the anode of the green light-emitting device 30G, and the thickness of the anode of the green light-emitting device 30G is less than a thickness of the anode of the blue light-emitting device 30B.

As shown in FIG. 1, a thickness of the first transparent electrode 311R of the red light-emitting device 30R is equal to a thickness of the first transparent electrode 311G of the green light-emitting device 30G and a thickness of the first transparent electrode 311B of the blue light-emitting device 30B. A thickness of the first metal electrode 312R of the red light-emitting device 30R is equal to a thickness of the first metal electrode 312G of the green light-emitting device 30G and a thickness of the first metal electrode 312B of the blue light-emitting device 30B. The thickness of the second transparent electrode 313R of the red light-emitting device 30R is smaller than the thickness of the second transparent electrode 313G of the green light-emitting device 30G, and the thickness of the second transparent electrode 313G of the green light-emitting device 30G is smaller than the thickness of the second transparent electrode 313B of the blue light-emitting device 30G.

As shown in FIG. 1, the light-emitting device layer 3 further includes a pixel definition layer 34. The pixel definition layer 34 is provided on a side of the driving circuit layer 2 away from the substrate 1. The pixel definition layer 34 is provided with a plurality of pixel openings (apertures). Each light-emitting layer 32 is provided inside a corresponding pixel opening.

In some embodiments, both the first transparent electrode 311 and the second transparent electrode 313 are made of a transparent metal oxide conductive material, and the transparent metal oxide conductive material may include indium tin oxide or indium zinc oxide.

In some embodiments, a material of the first metal electrode 312 is silver.

In some embodiments, the light-emitting device 30 is a quantum dot light-emitting diode. The light-emitting layer 32 at least includes a hole injection layer 321, a hole transport layer 322, an emissive material layer 323, an electron transport layer 324, and electron injection layer 325, which are sequentially stacked on a surface of the anode 31 away from the driving circuit layer 2. A material of the emissive material layer 323 includes a quantum dot material.

In some other embodiments, a type of the light-emitting device 30 is not limited to the quantum dot light-emitting diode in the above embodiments but may be an organic light-emitting diode, and the material of the emissive material layer 323 includes an organic light-emitting material.

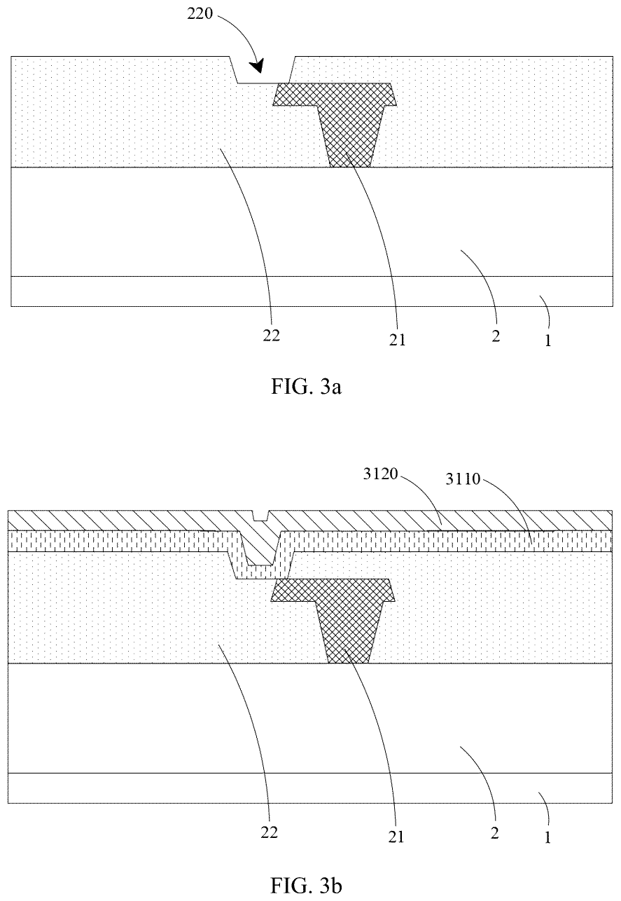

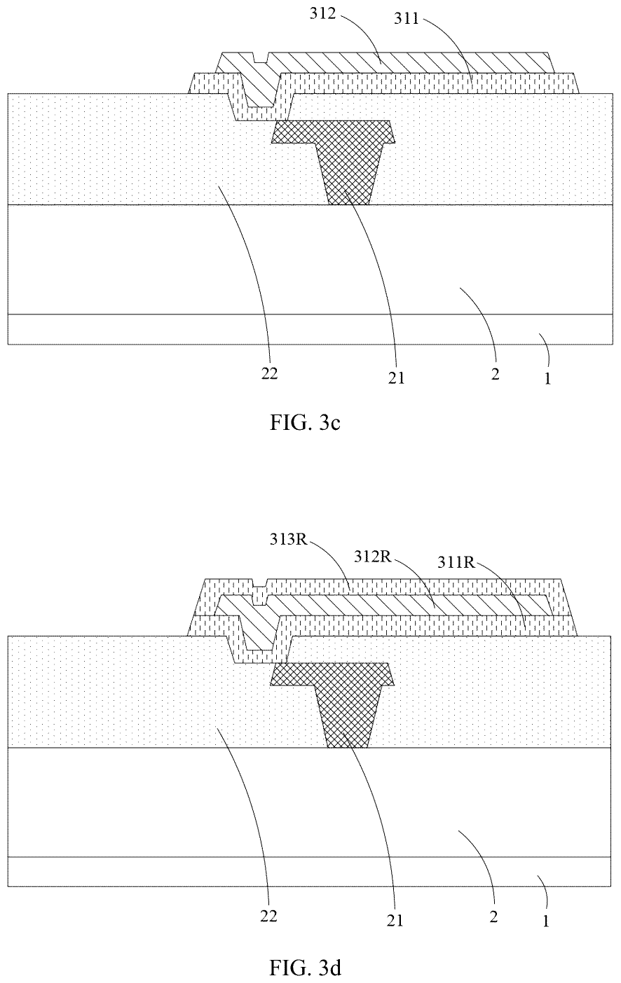

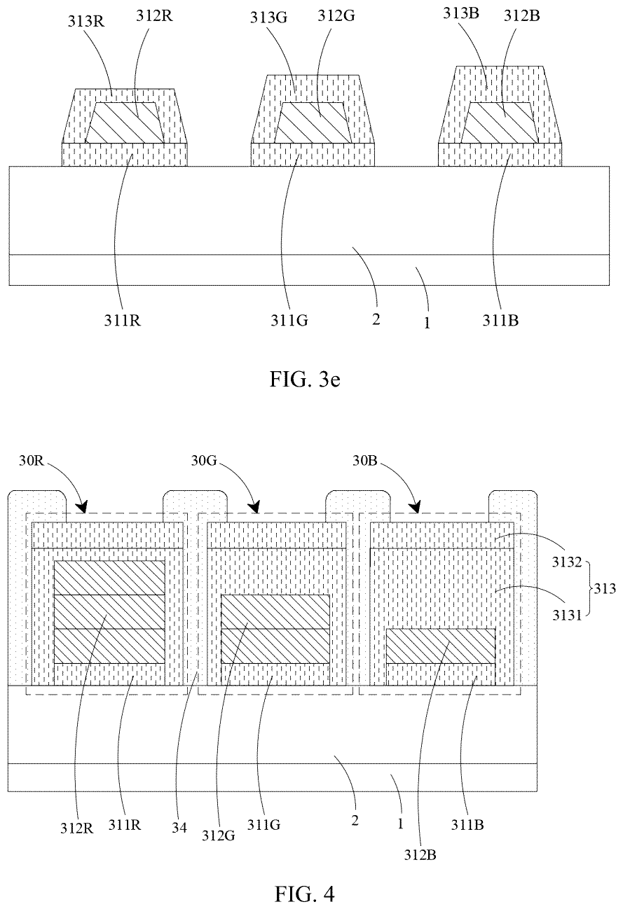

FIGS. 3a to 3e are schematic diagrams of a manufacturing process of the first display panel according to some embodiments of the present disclosure. With reference to FIGS. 3a to 3c, the manufacturing method of the display panel includes the following operations.

In operation 1, a driving circuit layer 2 is formed on a substrate 1.

As shown in FIG. 3a, the driving circuit layer 2 includes a source and drain electrode layer 21 provided on the substrate 1 and a planarization layer 22 provided on the substrate 1 and the source and drain electrode layer 21. An opening 220 is formed on the planarization layer 22 to expose part of the source and drain electrode layer 21.

In operation 2, a first transparent electrode material layer 3110 and a first metal electrode material layer 3120 are formed on the planarization layer 22 in sequence.

As shown in FIG. 3b, the first transparent electrode material layer 3110 is arranged flat on a surface of the planarization layer 22 away from the substrate 1, and the first transparent electrode material layer 3110 engages with the source and drain electrode layer 21 through the opening 220.

In operation 3, the first transparent electrode material layer 3110 and the first metal electrode material layer 3120 are etched to form a first transparent electrode 311 and a first metal electrode 312.

As shown in FIG. 3b and FIG. 3c, the first metal electrode material layer 3120 is laterally etched more than the first transparent electrode material layer 3110, such that a peripheral edge of the first transparent electrode 311 exceed a peripheral edge of the first metal electrode 312.

In operation 4, a second transparent electrode material layer is formed on the first transparent electrode 311, the first metal electrode 312, and the planarization layer 22, and is etched to form a second transparent electrode 313, for example a second transparent electrode 313R of a red light-emitting device 30R. And in this case, the previously formed first transparent electrode 311 and first metal electrode 312 are the first transparent electrode 311R and the first metal electrode 312R of the red light-emitting device 30R.

As shown in FIG. 3d, the second transparent electrode 313R of the red light-emitting device 30R continuously covers a top surface of the first metal electrode 312R away from the first transparent electrode 311R and side surface of the first metal electrode 312R. The second transparent electrode 313R also covers a surface part of the transparent electrode 311R that is not covered by the first metal electrode 312R. The first transparent electrode 311R and the second transparent electrode 313R form an enveloping structure for the first metal electrode 312R.

In operation 5, the second transparent electrode 313R is annealed.

As shown in FIG. 3c, an annealing operation is performed on the second transparent electrode 313R, such that crystal grains are formed inside the second transparent electrode 313R, and the grain boundaries inside the second transparent electrode 313R gradually disappear, so that the second transparent electrode 313R presents better continuity and uniformity, which may not only improve conductivity and light transmittance of the second transparent electrode 313R, but also ensure that a formed pattern structure is not affected by subsequent processes and effectively prevent any sharp protrusion on the edge of the first metal electrode 312R from piercing the second transparent electrode 313R and therefore contacting the cathode 33.

In operation 6, as shown in FIG. 3e, a third transparent electrode material layer is formed on the first transparent electrode 311, the first metal electrode 312, and the planarization layer 22, and is etched to form a second transparent electrode 313G on the first metal electrode 312G of the green light-emitting device 30G, and the second transparent electrode 313G is annealed. A fourth transparent electrode material layer is formed on the first transparent electrode 311, the first metal electrode 312, and the planarization layer 22, and is etched to form a second transparent electrode 313B on the first metal electrode 312B of the blue light-emitting device 30B, and the second transparent electrode 313B is annealed.

It should be noted that the above operations only illustrate part of the manufacturing process of the display panel. Other subsequent manufacturing processes of the display panel can refer to the manufacturing process of the existing display panels and will not be described again here. It is understood that FIG. 3a here (and FIGS. 3b-3c) only illustrates one opening 220 which corresponds to one light-emitting device to be prepared on the driving circuit layer 2, for example the red light-emitting device 30R shown in FIG. 4, but in practice there may be multiple openings 220 formed on the planarization layer 22 corresponding to multiple light-emitting devices to be prepared, for example the red light-emitting device 30R, the green light-emitting device 30G and the blue light-emitting device 30B shown in FIG. 4.

FIG. 4 is a schematic structural diagram of a second display panel according to some embodiments of the present disclosure. As shown in FIG. 4, its structure is basically the same as that of the display panel described in FIG. 1, except that the second transparent electrode 313 is continuously disposed on the side surface of the first metal electrode 312 and on the side surface of the first transparent electrode 311. Similar to the side surface of the second metal electrode 312, the side surface of the first transparent electrode 311 refers to its entire side surface, which may by a cylindrical surface of a cylindrical first transparent electrode 311, or four side surfaces of a square first transparent electrode 311, or the like.

As shown in FIG. 4, the second transparent electrode 313 is continuously disposed on the top surface of the first metal electrode 312 away from the first transparent electrode 311, the side surface of the first metal electrode 312, and the side surface of the first transparent electrode 311. The first transparent electrode 311 and the second transparent electrode 313 form an enveloping structure for the first metal electrode 312, completely isolating the first metal electrode 312 from the light-emitting layer 32 and the cathode 33, thereby avoiding the contact between the cathode 33 and any sharp protrusion formed on the edge of the first metal electrode 312, thereby further avoiding the short circuit in the light emitting device 30 due to the contact between the cathode 33 and the anode 31.

In some embodiments, as shown in FIG. 4, a thickness of the first metal electrode 312R of the red light-emitting device 30R is greater than or equal to a thickness of the first metal electrode 312G of the green light-emitting device 30G, and the thickness of the first metal electrode 312G of the green light-emitting device 30G is greater than a thickness of the first metal electrode 312B of the blue light-emitting device 30B. A thickness of the second transparent electrode 313R of the red light-emitting device 30R is smaller than a thickness of the second transparent electrode 313G of the green light-emitting device 30G, and the thickness of the second transparent electrode 313G of the green light-emitting device 30G is smaller than a thickness of the second transparent electrode 313B of the blue light emitting device 30B. In this way, different light-emitting devices may have different microcavity lengths, thereby improving the light coupling efficiency of each light-emitting device, thereby improving the luminous efficiency of each light-emitting device.

In some embodiments, the second transparent electrode 313 includes a first transparent sub-electrode 3131 and a second transparent sub-electrode 3132. The second transparent sub-electrode 3132 is disposed on a side of the first transparent sub-electrode 3131 away from the first metal electrode 312. The first transparent sub-electrode 3131 is manufactured by a solution method, and the second transparent sub-electrode 3132 is manufactured by a sputtering coating process. Surface roughness of the first transparent sub-electrode 3131 is greater than surface roughness of the second transparent sub-electrode 3132.

In some embodiments, a surface of the anode 31 of the red light-emitting device 30R away from the substrate 1 is flush with a surface of the anode 31 of the green light-emitting device 30G away from the substrate 1 and a surface of the anode 31 of the blue light-emitting device 30B away from the substrate 1. Since the first transparent sub-electrode 3131 is prepared by the solution method, and the transparent conductive solution has a leveling property. After the first transparent sub-electrode 3131 is formed, the top surfaces of the first transparent sub-electrodes 3131 of the red light-emitting device 30R, the green light-emitting device 30G, and the blue light-emitting device 30B are all in a same plane. The top surfaces of the second transparent sub-electrodes 3132 of the red light-emitting device 30R, the green light-emitting device 30G, and the blue light-emitting device 30B subsequently formed by the sputtering coating process are also in a same plane. In this way, a top surface of the anode 31 of the red light-emitting device 30R away from the substrate 1 is flush with a top surface of the anode 31 of the green light-emitting device 30G away from the substrate 1 and a top surface of the anode 31 of the blue light-emitting device 30B away from the substrate 1, which may further improve the flatness of the subsequently formed light-emitting layer 32 and the cathode 33 to realize an ideal light pattern.

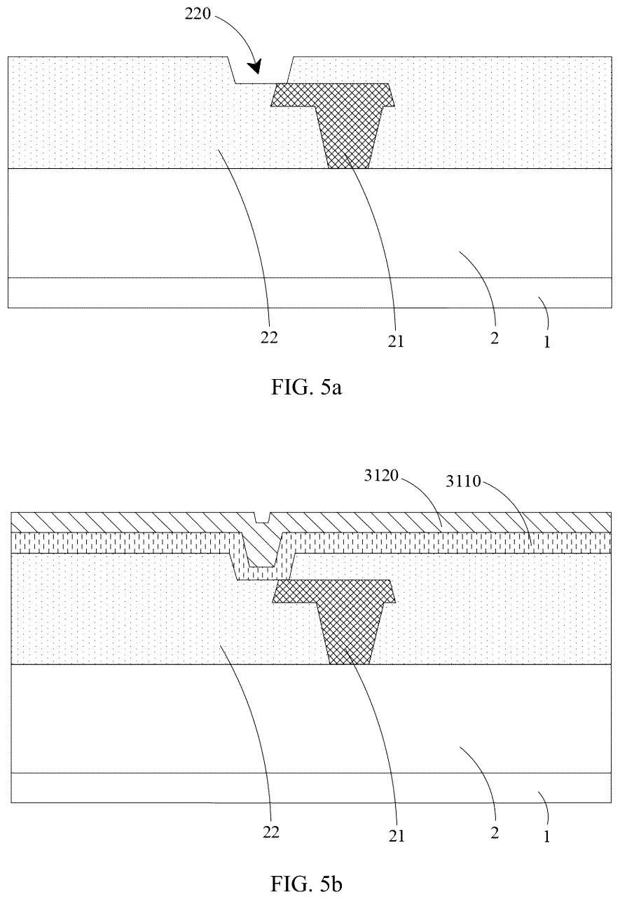

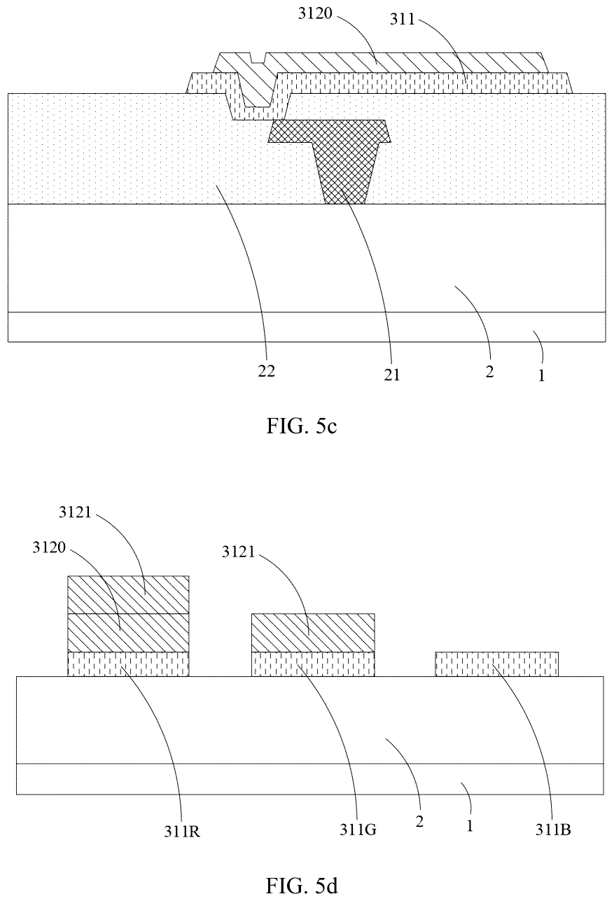

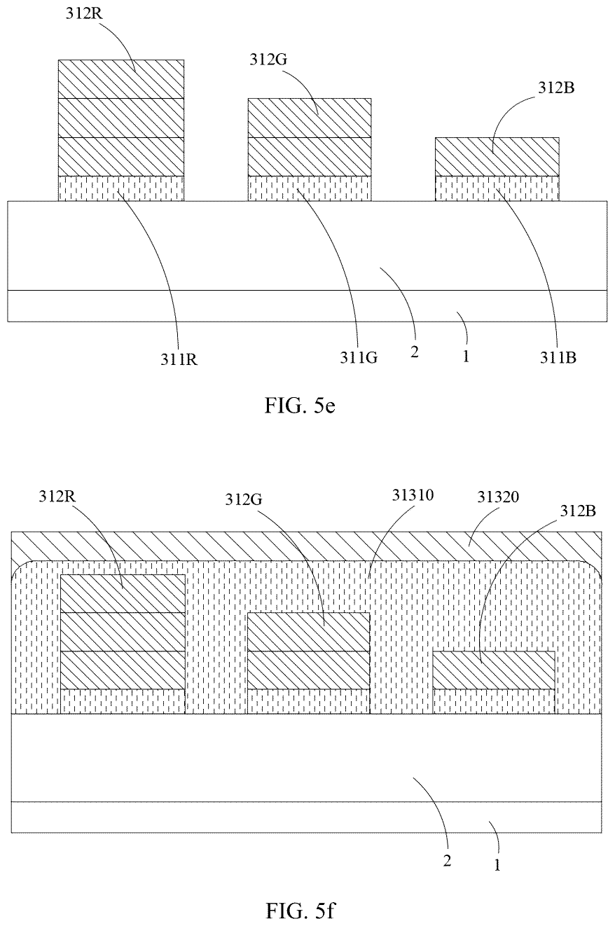

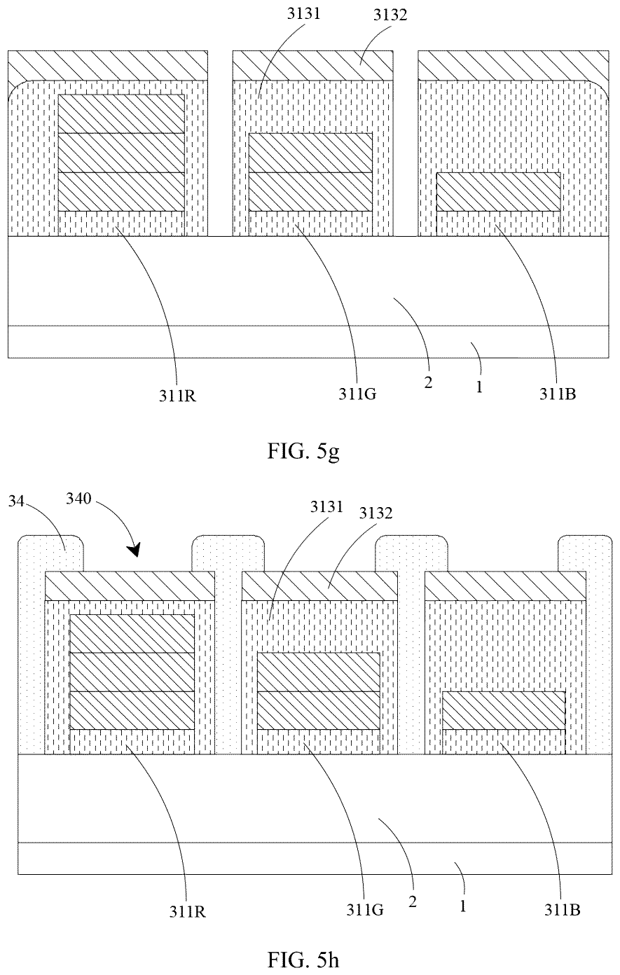

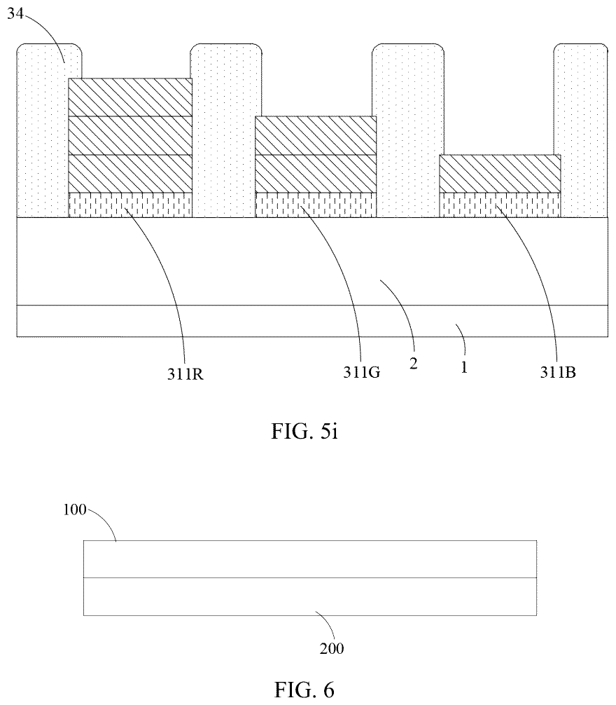

FIGS. 5a to 5i are schematic diagrams showing a manufacturing process of the second display panel according to some embodiments of the present disclosure. With reference to FIGS. 5a to 5i, the manufacturing method of the display panel includes the following operations.

In operation 1, a driving circuit layer 2 is formed on a substrate 1.

As shown in FIG. 5a, the driving circuit layer 2 includes a source and drain electrode layer 21 provided on the substrate 1 and a planarization layer 22 provided on the substrate 1 and on the source and drain electrode layer 21. An opening 220 is formed on the planarization layer 2 to expose part of the source and drain electrode layer 21.

In operation 2, a first transparent electrode material layer 3110 and a first metal electrode material layer 3120 are formed on the planarization layer 22 in sequence.

As shown in FIG. 5b, the first transparent electrode material layer 3110 is arranged flat on a surface of the planarization layer 22 away from the substrate 1, and the first transparent electrode material layer 3110 engages with the source and drain electrode layer 21 through the opening 220.

In operation 3, the first transparent electrode material layer 3110 and the first metal electrode material layer 3120 are etched to form a first transparent electrode 311.

As shown in FIG. 5b and FIG. 5c, the first metal electrode material layer 3120 is laterally etched more than the first transparent electrode material layer 3110, and a peripheral edge of the first transparent electrode 311 exceed a peripheral edge of the etched first metal electrode material layer 3120.

In operation 4, a second metal electrode material layer 3121 is formed on the first metal electrode material layer 3120 and the first transparent electrode 311 and is etched.

As shown in FIG. 5d, a part of the second metal electrode material layer 3121 is located on the first metal electrode material layer 3120, and another part of the second metal electrode material layer 3121 is located on the first transparent electrode 311.

In operation 5, a third metal electrode material layer is formed on the second metal electrode material layer 3121 and the first transparent electrode 311 and is etched.

As shown in FIG. 4 and FIG. 5c, a part of the third metal electrode material layer is located on the second metal electrode material layer 3121 disposed on the first metal electrode material layer 3120, and forms the first metal electrode 312R of the red light-emitting device 30R with the lower second metal electrode material layer 3121 and the first metal electrode material layer 3120. Another part of the third metal electrode material layer is located on the second metal electrode material layer 3121 disposed on the first transparent electrode 311G, and forms the first metal electrode 312G of the green light-emitting device 30G with the lower second metal electrode material layer 3121. Another part of the third metal electrode material layer is located on the first transparent electrode 311, and serves as the first metal electrode 312B of the blue light-emitting device 30B. In this way, the thickness of the first metal electrode 312R of the red light-emitting device 30R is greater than or equal to the thickness of the first metal electrode 312G of the green light-emitting device 30G, and the thickness of the first metal electrode 312G of the green light-emitting device 30G is greater than the thickness of the first metal electrode 312B of the blue light-emitting device 30B.

In operation 6, a first transparent sub-electrode material layer 31310 is formed using a solution method, and a second transparent sub-electrode material layer 31320 is formed on the first transparent sub-electrode material layer 31310 using a sputtering coating process.

As shown in FIG. 5f, the first transparent sub-electrode solution has a leveling property, and the manufactured first transparent sub-electrode material layer 31310 has a flat surface. The second transparent sub-electrode material layer 31320 formed by the sputtering coating process also has a flat surface. Surface roughness of the first transparent sub-electrode material layer 31310 is greater than surface roughness of the second transparent sub-electrode material layer 31320.

In operation 7, the first transparent sub-electrode material layer 31310 and the second transparent sub-electrode material layer 31320 are etched to form a first transparent sub-electrode 3131 and a second transparent sub-electrode 3132.

As shown in FIG. 5g, the first transparent sub-electrode material layer 31310 and the second transparent sub-electrode material layer 31320 are etched to form the first transparent sub-electrode 3131 and the second transparent sub-electrode 3132, with a groove between adjacent sub-electrodes.

In operation 8, as shown in FIG. 5h, a pixel definition layer 34 is formed on the second transparent sub-electrode 3132 and is etched to form a plurality of pixel openings 340.

In some embodiments, as shown in FIG. 5i, in order to avoid a poor etching effect due to an excessive thickness of the first transparent sub-electrode material layer 31310 and second transparent sub-electrode material layer 31320, the pixel definition layer 34 may be formed after the first metal electrode 312R, the first metal electrode 312G, and the first metal electrode 312B are formed, and before the forming of the first transparent sub-electrode material layer 31310 and of the second transparent sub-electrode material layer 31320, and finally the first transparent sub-electrode material layer 31310 and the second transparent sub-electrode material layer 31320 are etched to form the first transparent sub-electrode 3131 and the second transparent sub-electrode 3132.

It should be noted that the above operations only illustrate part of the manufacturing process of the display panel. Other subsequent manufacturing processes of the display panel can refer to the manufacturing process of the existing display panel, and will not be described again here.

Some embodiments of the present disclosure further provide a display device, as shown in FIG. 6. FIG. 6 is a schematic structural diagram of the display device according to some embodiments of the present disclosure. The display device includes a display panel 100 and a housing 200. The display panel 100 is disposed on the housing 20. The display panel 100 may be the display panel provided in any of the above embodiments.

Beneficial effects of the embodiments of the present disclosure are as follows. the embodiments of the present disclosure provide a display panel(s) and a display device(s). The display panel includes a substrate, a driving circuit layer, and a light-emitting device layer. The light-emitting device layer includes a plurality of light-emitting devices. Each light-emitting device includes an anode, a light-emitting layer, and a cathode. The anode includes a first transparent electrode, a first metal electrode, and a second transparent electrode. The first metal electrode is disposed on a side of the first transparent electrode away from the driving circuit layer, and the second transparent electrode is disposed on a side of the first metal electrode away from the first transparent electrode, the second transparent electrode covers the edge of the first metal electrode, which can prevent the cathode from contacting any protrusion formed on the edge of the first metal electrode. This can prevent the cathode from direct contact with the anode and causing a short circuit, which prevents the light-emitting device from failing to emit light, thereby mitigating the occurrence of the dark spots on the display panel.

In summary, although the present disclosure has been disclosed as above with some embodiments, the above embodiments are not intended to limit the present disclosure. Those of ordinary skill in the art can make various modifications without departing from the spirit and scope of the present disclosure. Therefore, the protection scope of this application is based on the scope defined by the claims.

What is claimed is:

1. A display panel, comprising:
a substrate;
a driving circuit layer disposed on one side of the substrate;
a light-emitting device layer disposed on one side of the driving circuit layer away from the substrate, wherein the light-emitting device layer comprises a plurality of light-emitting devices,
each light-emitting device comprises an anode, a light-emitting layer, and a cathode, wherein the light-emitting layer is disposed on one side of the anode away from the driving circuit layer, and the cathode is disposed on one side of the light-emitting layer away from the anode,
the anode comprises a first transparent electrode, a first metal electrode, and a second transparent electrode, the first metal electrode is disposed on one side of the first transparent electrode away from the driving circuit layer, the second transparent electrode is disposed on one side of the first metal electrode away from the first transparent electrode, and the first metal electrode is wrapped between the first transparent electrode and the second transparent electrode.

2. The display panel of claim 1, wherein the second transparent electrode is continuously disposed on a surface of the first metal electrode away from the first transparent electrode and on a side surface of the first metal electrode.

3. The display panel of claim 2, wherein an orthographic projection of the first metal electrode on the substrate is located within an orthographic projection of the second transparent electrode on the substrate.

4. The display panel of claim 3, wherein an orthographic projection of the first metal electrode on the first transparent electrode is located within the first transparent electrode.

5. The display panel of claim 3, wherein the second transparent electrode is continuously disposed on the side surface of the first metal electrode and on a side surface of the first transparent electrode.

6. The display panel of claim 1, wherein the plurality of light-emitting devices comprise a red light-emitting device, a green light-emitting device, and a blue light-emitting device,
a surface of the anode of the red light-emitting device away from the substrate is lower than a surface of the anode of the green light-emitting device away from the substrate, and the surface of the anode of the green light-emitting device away from the substrate is lower than a surface of the anode of the blue light-emitting device away from the substrate.

7. The display panel of claim 1, wherein the plurality of light-emitting devices comprise a red light-emitting device, a green light-emitting device, and a blue light-emitting device,
a surface of the anode of the red light-emitting device away from the substrate is flush with a surface of the anode of the green light-emitting device away from the substrate and a surface of the anode of the blue light-emitting device away from the substrate.

8. The display panel according to claim 1, wherein the plurality of light-emitting devices comprise a red light-emitting device, a green light-emitting device, and a blue light-emitting device,
a thickness of the second transparent electrode of the red light-emitting device is smaller than a thickness of the second transparent electrode of the green light-emitting device, and the thickness of the second transparent electrode of the green light-emitting device is smaller than a thickness of the second transparent electrode of the blue light-emitting device.

9. The display panel of claim 8, wherein a thickness of the first metal electrode of the red light-emitting device is greater than or equal to a thickness of the first metal electrode of the green light-emitting device, and the thickness of the first metal electrode of the green light-emitting device is greater than or equal to a thickness of the first metal electrode of the blue light-emitting device.

10. The display panel of claim 9, wherein each second transparent electrode comprises a first transparent sub-electrode and a second transparent sub-electrode, the second transparent sub-electrode is disposed on one side of the first transparent sub-electrode away from the first metal electrode adjacent to the second transparent electrode, and
surface roughness of the first transparent sub-electrode is greater than surface roughness of the second transparent sub-electrode.

11. A method for manufacturing a display panel comprising at least a red light-emitting device, a green light-emitting device, and a blue light-emitting device, comprising:
forming a substrate;
forming a driving circuit layer on the substrate;
forming a first transparent electrode material layer and a first metal electrode material layer on the driving circuit layer in sequence;
etching the first transparent electrode material layer and the first metal electrode material layer to form a first transparent electrode and a first metal electrode of each of the red light-emitting device, the green light-emitting device, and the blue light-emitting device;
forming a second transparent electrode material layer on each first transparent electrode, each first metal electrode, and the driving circuit layer, and etching the second transparent electrode material layer to form a second transparent electrode of the red light-emitting device and expose the first metal electrode of the green light-emitting device and the first metal electrode of the blue light-emitting device;
forming a third transparent electrode material layer on each first transparent electrode, each first metal electrode, each second transparent electrode, and the driving circuit layer, and etching the third transparent electrode material layer to form a second transparent electrode of the green light-emitting device and expose the second transparent electrode of the red light-emitting device and the first metal electrode of the blue light-emitting device; and
forming a fourth transparent electrode material layer on each first transparent electrode, each first metal electrode, each second transparent electrode, and the driving circuit layer, and etching the fourth transparent electrode material layer to form a second transparent electrode of the blue light-emitting device and expose the second transparent electrode of the red light-emitting device and the second transparent electrode of the green light-emitting device.

12. The method of claim 11, wherein the second transparent electrode of each light-emitting device is continuously disposed on a surface of the first metal electrode of the light-emitting device away from the first transparent electrode and on a side surface of the first metal electrode.

13. The method of claim 12, wherein an orthographic projection of the first metal electrode of each light-emitting device on the substrate is located within an orthographic projection of the second transparent electrode of the light-emitting device on the substrate.

14. The method of claim 13, wherein an orthographic projection of the first metal electrode of each light-emitting device on the first transparent electrode is located within the first transparent electrode of the light-emitting device.

15. The method of claim 11, wherein a surface of the second transparent electrode of the red light-emitting device away from the substrate is lower than a surface of the second transparent electrode of the green light-emitting device away from the substrate, and the surface of the second transparent electrode of the green light-emitting device away from the substrate is lower than a surface of the second transparent electrode of the blue light-emitting device away from the substrate.

16. The method of claim 11, wherein a thickness of the second transparent electrode of the red light-emitting device is smaller than a thickness of the second transparent electrode of the green light-emitting device, and the thickness of the second transparent electrode of the green light-emitting device is smaller than a thickness of the second transparent electrode of the blue light-emitting device.

17. A method for manufacturing a display panel comprising at least a red light-emitting device, a green light-emitting device, and a blue light-emitting device, comprising:
forming a substrate;
forming a driving circuit layer on the substrate;
forming a first transparent electrode material layer and a first metal electrode material layer on the driving circuit layer in sequence;
etching the first transparent electrode material layer and the first metal electrode material layer to form a first transparent electrode of each of the red light-emitting device, the green light-emitting device, and the blue light-emitting device, and expose the first transparent electrode of each of the green light-emitting device and the blue light-emitting device while leave a top surface of the first transparent electrode of the red light-emitting device being covered by a remaining part of the first metal electrode material;
forming a second metal electrode material layer on the remaining part of first metal electrode material layer, and each first transparent electrode, and etching the second metal electrode material layer to expose the first transparent electrode of the blue light-emitting device while leave a top surface of the remaining part of first metal electrode material layer of the red light-emitting device and a top surface of the first transparent electrode of the green light-emitting device being covered by a remaining part of the second metal electrode material;
forming a third metal electrode material layer on the second metal electrode material layer and the first transparent electrode, and etching the third metal electrode material layer to form a first metal electrode of each of the red light-emitting device, the green light-emitting device, and the blue light-emitting device;
forming a first transparent sub-electrode material layer on the driving circuit layer and each first metal electrode;
forming a second transparent sub-electrode material layer on the first transparent sub-electrode material layer;
etching the first transparent sub-electrode material layer and the second transparent sub-electrode material layer to form a first transparent sub-electrode and a second transparent sub-electrode of each light-emitting device; and
forming a pixel definition layer on each second transparent sub-electrode and the driving circuit layer, and etching the pixel definition layer to form at least three pixel openings respectively corresponding to the red light-emitting device, the green light-emitting device, and the blue light-emitting device.

18. The method of claim 17, wherein the first transparent sub-electrode of each light-emitting device is continuously disposed on a surface of the first metal electrode of the light-emitting device away from the first transparent electrode, on a side surface of the first metal electrode, and on a side surface of the first transparent electrode of the light-emitting device.

19. The method of claim 18, wherein an orthographic projection of the first metal electrode of each light-emitting device on the substrate is located within an orthographic projection of the first transparent sub-electrode and the second transparent electrode of the light-emitting device on the substrate.

20. The method of claim 17, wherein the forming of the first transparent sub-electrode material layer comprises forming the first transparent sub-electrode material layer using a solution method, and
the forming of the second transparent sub-electrode material layer comprises forming the second transparent sub-electrode material layer using a sputtering coating process.
